(19) United States
(12) Patent Application Publication
(10) Pub. No.: US 2024/0201225 A1
(43) Pub. Date: Jun. 20, 2024

(54) MEMS probes having decoupled electrical and mechanical design

(71) Applicant: FormFactor, Inc., Livermore, CA (US)

(72) Inventors: Kevin John Hughes, Jurupa Valley, CA (US); January Kister, Portola Valley, CA (US)

(21) Appl. No.: 18/391,228

(22) Filed: Dec. 20, 2023

Related U.S. Application Data
(60) Provisional application No. 63/433,904, filed on Dec. 20, 2022.

(51) Int. Cl. G01R 1/073

(52) U.S. Cl. CPC G01R 1/07307

(57) ABSTRACT

MEMS probes are provided having decoupled electrical and mechanical design. In these probes, electrical conduction is primarily through one or more electrically conductive rails, and mechanical compliance for vertical compression is provided by a coil. The resulting independence of electrical and mechanical design advantageously enables probes to have a combination of electrical and mechanical properties that cannot be obtained in probes where the probe body is subject to both electrical and mechanical design constraints.

### CROSS REFERENCE TO RELATED APPLICATIONS

This application claims priority from U.S. Provisional Patent Application 63/433904 filed Dec. 20, 2022, which is incorporated herein by reference.

### FIELD OF THE INVENTION

This invention relates to vertical probes for testing electrical devices.

### BACKGROUND

Test fixtures including an array of vertical probes are often used for testing electrical devices. The vertical probes make temporary electrical contact to the device under test. Here vertical probes (in contrast to cantilever probes) are substantially vertically disposed in the probe head, relative to the device under test. Vertical probes are often preferred in situations where the device under test has a large number of contacts (e.g., wafer-scale probing), since vertical probes can provide more contacts in a given probe head area than cantilever probes. In conventional vertical probes, the body of the probe “does all the work” in the sense that it is the electrical path and also provides all the mechanical compliance and mechanical contact force. These shared responsibilities force undesirable design trade-offs between current carrying capacity (CCC), contact force, overtravel (the vertical distance through which a probe is compressed when it makes contact), and electrical signal/power integrity.

At higher electrical frequencies (e.g., 5-10 GHz and above) electrical and mechanical design requirements for vertical probes come into sharp conflict. Electrical design considerations at these frequencies tend to lead to short probes with highly undesirable mechanical properties, such as overly limited vertical deflection range and high susceptibility to damage from particles.

Accordingly, it would be an advance in the art to provide vertical probes having improved electrical and mechanical design.

### SUMMARY

This work addresses this problem by providing vertical probes having decoupled electrical and mechanical design. The basic idea in some embodiments is for each probe to include electrically conductive rail(s) along with a mechanically resilient coil, where the coil provides the desired mechanical resilience properties, and the rail(s) provide the main electrical current path. The coil makes electrical contact to the rail(s) at the base and tip of the probe. This electrical contact at the base of the probe can be accomplished by affixing the rail(s) to the coil at the base of the probe. The electrical contact between the rail(s) and the coil at the tip of the probe can be a sliding electrical contact. Even if the rail(s) and coil are made of the same material (or same multi-layer stack), the more direct path for current provided by the rail(s) can lead to it preferentially carrying the current, as desired.

Two main variants of this design are considered, which differ in the geometrical relation of the rail(s) to the MEMS layer stack. We define the deposition direction of the probe as the deposition direction of its MEMS multilayer stack. This deposition direction is perpendicular to the vertical axis of the probe, and we define the “horizontal” direction as the direction perpendicular to both the deposition direction and the vertical direction.

In the side-rail variant, two rails sandwich the coil in the horizontal direction. For the side-rail variant, the rails and the coil can have the same multilayer stack structure or different multi-layer stack structures.

In the rail-on-back variant, the MEMS layer structure has two distinct parts along the deposition direction—a first part that defines the coil and a second part that defines the rail. Here the rail and the coil are formed from different layers of the multilayer stack.

### BRIEF DESCRIPTION OF THE DRAWINGS

FIGS. 1A-B show an exemplary embodiment of the invention.

FIGS. 2A-B show a first example of tensile protection.

FIGS. 3A-C show a second example of tensile protection.

FIGS. 4A-B show a first example of scrub motion control.

FIGS. 5A-B show a second example of scrub motion control.

FIGS. 6A-B show a third example of scrub motion control.

FIGS. 7A-D show a second embodiment of the invention.

FIGS. 8A-D schematically show several probe array configurations.

FIGS. 9A-B show an example of two guide plates.

FIGS. 9C-D show another example of two guide plates.

FIGS. 10A-B show an example of three guide plates.

FIGS. 11A-B show a first example of angled guide plate holes.

FIGS. 12A-B show a second example of angled guide plate holes.

### DETAILED DESCRIPTION

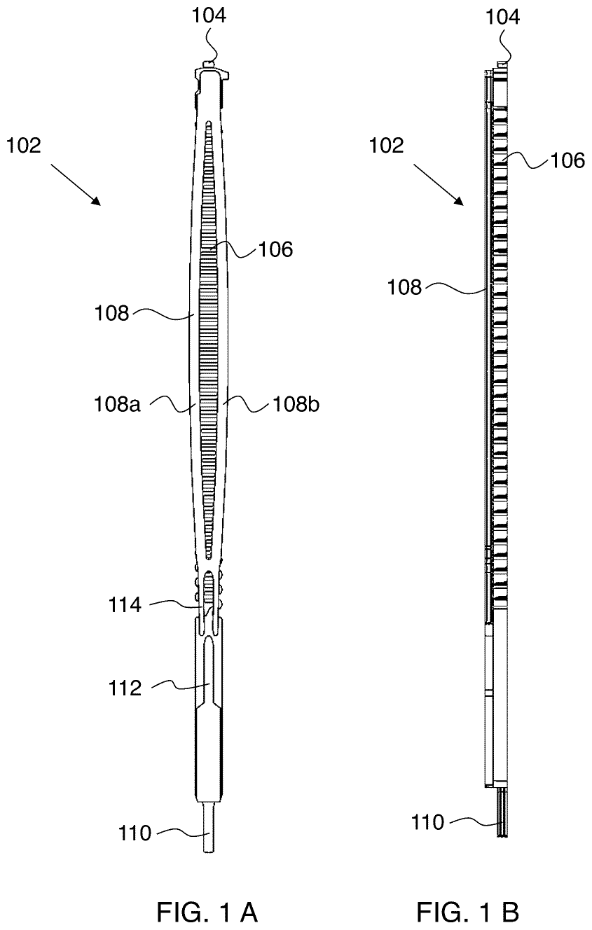

FIGS. 1A-B show a first embodiment of the invention. This is an example of the rail-on-back variant described above. FIGS. 1A and 1B are front and side views, respectively, of probe 102 that includes a mechanically resilient first member 106 (i.e. the “coil” as described above) and an electrically conductive second member 108 (i.e., a “rail” as described above). Probe 102 also includes a probe tip 110 configured to make temporary electrical contact to a device under test, and a probe base 104 configured to make electrical contact to a test apparatus. The mechanical compliance between the probe tip and the probe base is primarily determined by the mechanically resilient first member. The electrical current path between the probe tip and the probe base is primarily through the at least one electrically conductive second member. The electrically conductive second member is affixed to the mechanically resilient first member at the probe base, as shown. As indicated above, coil and rail designs are decoupled. For example, the coil can be optimized for compliance, contact force, short vertical length (mechanical) and the rail can be optimized for electrical current carrying capacity and bandwidth (electrical). Another design refinement is for rail 108 to include retention features to engage with guide plate holes. In this example, these retention features are dual-sided flexure 108a, 108b in rail 108. This advantageously prevents probes from falling out of guide plate holes.

Note that the coil can be (and typically is) made of electrically conductive material(s) without changing the fact that current flow is primarily (i.e. 80% or more) through the rail(s). One reason for this is that the current path through the coil is much longer than the current path in the rail(s), thereby increasing the resistance. The typically larger cross section area of the rails(s) compared to the coil can also increase this resistance difference. The current between the base and tip of the probe will mainly take the path of least resistance, which is through the rail(s).

In this example, probe 102 is a multilayer MEMS (micro-electrical-mechanical systems) probe having a MEMS deposition direction (left <-> right on FIG. 1B), and the electrically conductive second member is disposed above or below the mechanically resilient first member in the MEMS deposition direction, as shown on FIG. 1B.

In one exemplary design of the rail-on-back variant, a probe having a probe size of 85×50×1600 μm had the following probe performance parameters: contact force 1.2-1.8 grams at 75 μμm overtravel, probe current carrying capacity 0.8 A (uncoated)/1.2 A (1 μm gold coating), bandwidth 10-25 GHz depending on plate material and dB criteria (−15 vs.−10 dB), stress at 100 um overtravel of 1.02 GPa, 0.68 grams sidewall retention force, and pincer grip force 0.25 grams.

Electrical contact between the tip of the probe and the electrically conductive second member is preferably provided by a slidable mechanical contact where the probe tip includes a tip feature 112 that mechanically engages with a corresponding rail feature 114 of the electrically conductive second member. Practice of the invention is not limited to any specific shape of the features of this slidable contact.

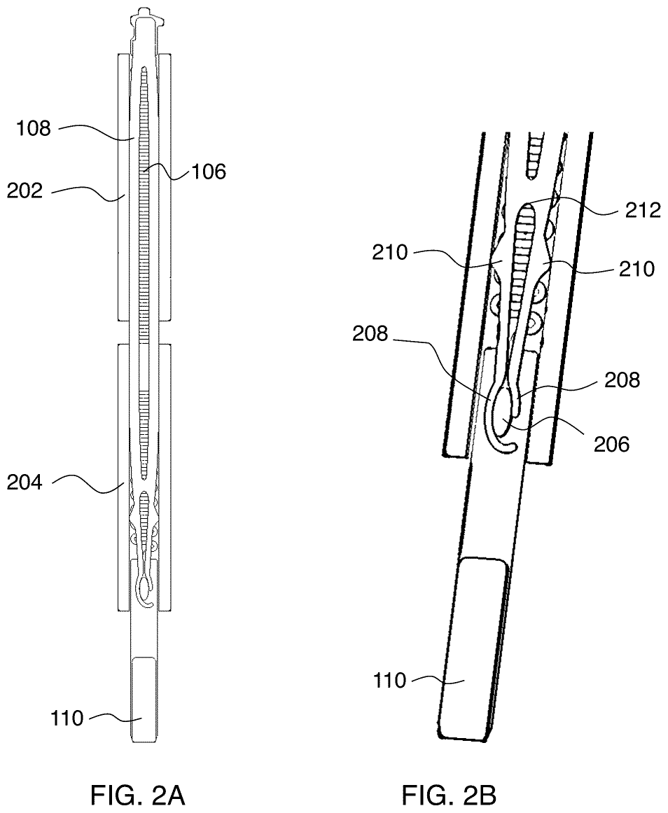

In preferred embodiments, the tip feature mechanically engages with the rail feature such that protection is provided against tension undesirably pulling the probe tip out of the probe. FIGS. 2A-B and 3A-B show two examples of such structures.

The example of FIGS. 2A-B show rail features 208 that engage with tip feature 206 to provide tensile protection. Here FIG. 2A shows the probe, and FIG. 2B is an enlarged view of the probe tip. This probe is shown disposed in guide plates 202 and 204. Features 208 include a hook (on the left) to provide this protection. Protrusions 210 on rail 108 engage with the guide plate to urge rail features 208 to flexibly engage with tip feature 206. In operation, tip 110 can move up on FIG. 1B until tip feature 106 engages with slot bottom 212 to accommodate probe overtravel, but downward motion of tip 110 on FIG. 1B is prevented by rail features 208.

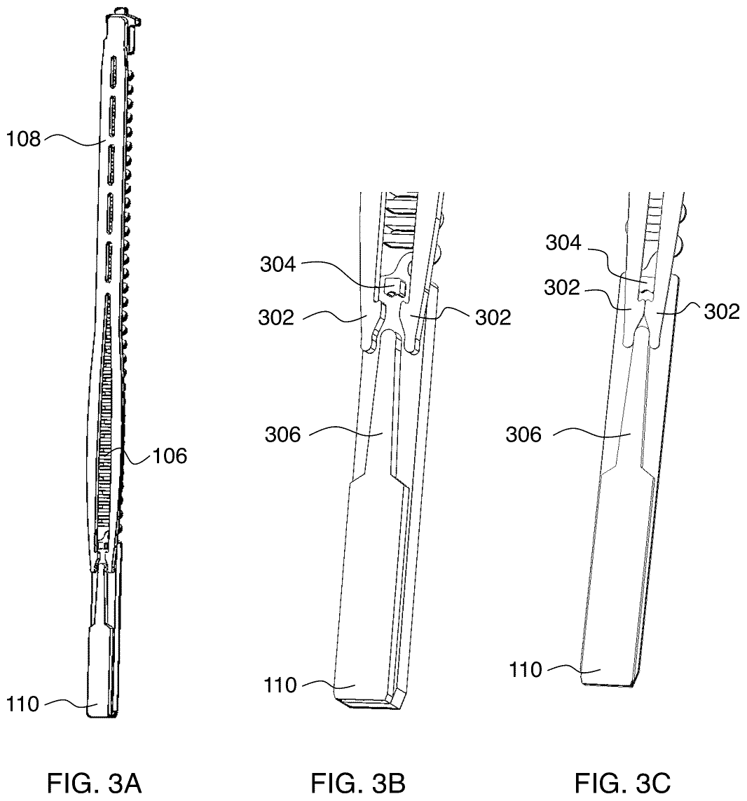

FIGS. 3A-C show another way to provide this capability. Here FIG. 3A shows the probe, FIG. 3B is an enlarged view of the probe tip when the probe is not disposed in a guide plate hole, and FIG. 3C is an enlarged view of the probe tip when the probe is disposed in a guide plate hole. Here the rail features 302 form a flexible pincer that is closed by deformation of the rail when the probe is disposed in a guide plate hole. The tip features include a ridge 306 and a motion-stop 304. Motion-stop 304 prevents significant downward motion of tip 110 on FIG. 3C by engaging with pincer 302. Probe overtravel is accommodated by a slidable engagement of ridge 304 with pincer 302.

Features of the tip and rail can also be used to determine the scrub motion of the tip as it makes contact to a contact pad of the device under test. If we let z be the vertical direction of the probe array, then conventional probe scrub motion is lateral (i.e., in the x-y plane). Such motion can be provided by embodiments of the invention. Some embodiments of the invention can provide a rotational scrub motion (i.e., a tip rotation about the z-axis) instead of or in addition to lateral scrub motion. Several examples are shown below.

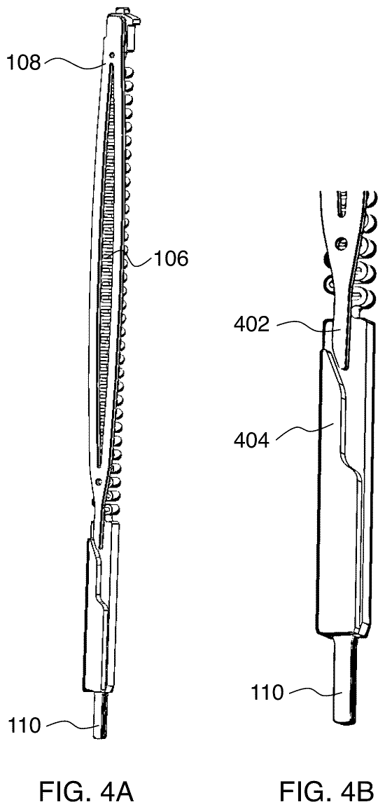

FIGS. 4A-B show a first example of defining scrub motion. Here scrub features 402 and 404 (of the rail and tip, respectively) are asymmetric. The left and right asymmetry on FIG. 4B mainly defines a lateral scrub motion. There is also a front-back symmetry on FIG. 4B which can lead to a rotational scrub motion.

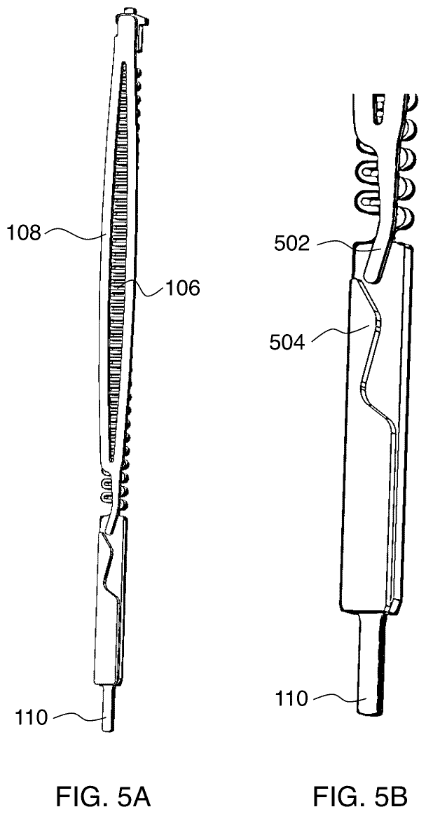

FIGS. 5A-B show a second example of defining scrub motion. Here scrub features 502 and 504 (of the rail and tip, respectively) engage to provide a “back and forth” scrub motion (with back being roughly half the forward excursion). The left and right asymmetry on FIG. 5B mainly defines a lateral scrub motion. There is also a front-back symmetry on FIG. 5B which can lead to a rotational scrub motion. Here the intent is to reach a maximum scrub distance at about 50 μm overtravel, then scrub about half way back at 75 μm overtravel. Feature 502 of rail 108 is tuned to be stiff enough to push the tip to scrub but has a small amount of flexibility to prevent hard binding and lock up when the tip is fully shifted. In one example of this approach, the lateral scrub motion was 4 μm XY travel and a 7 degree rotation about the probe axis.

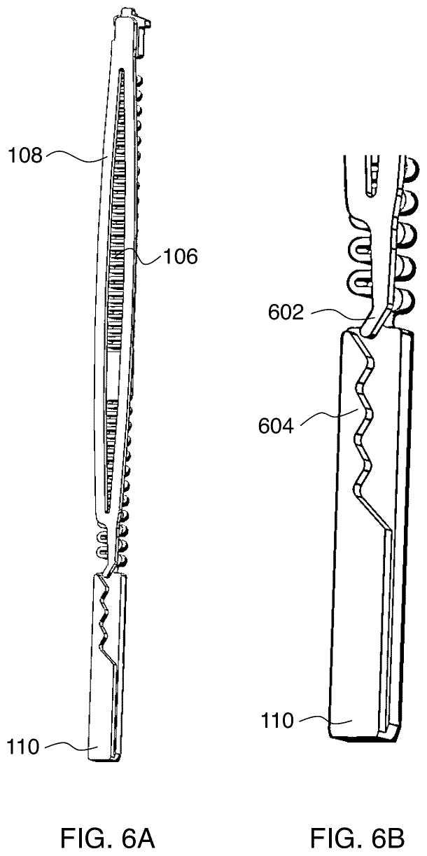

FIGS. 6A-B show a third example of defining scrub motion. Here scrub features 602 and 604 (of the rail and tip, respectively) engage to provide a repeated “back and forth” scrub motion. The left and right asymmetry on FIG. 6B mainly defines a lateral scrub motion. There is also a front-back symmetry on FIG. 6B which can lead to a rotational scrub motion.

Practice of the invention is not limited to these three examples. Any fabricable shapes can be used to define scrub motion, which provides unprecedented freedom in design of suitable scrub motions for various testing applications.

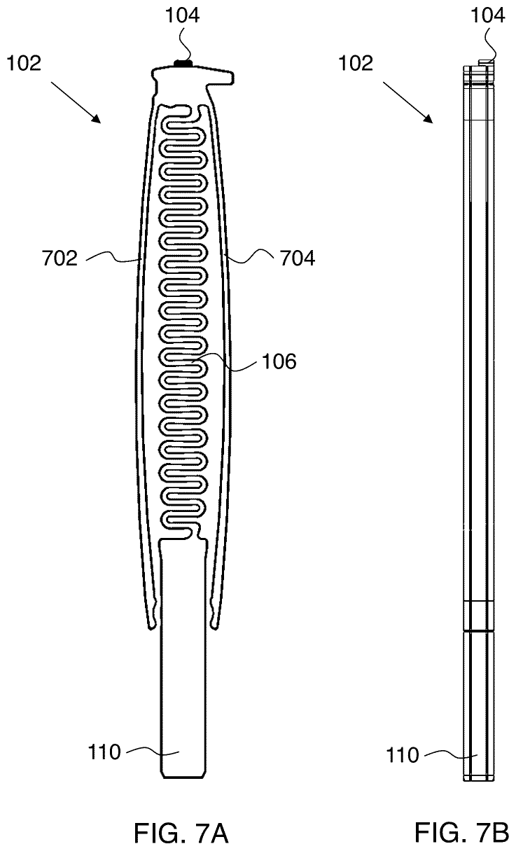

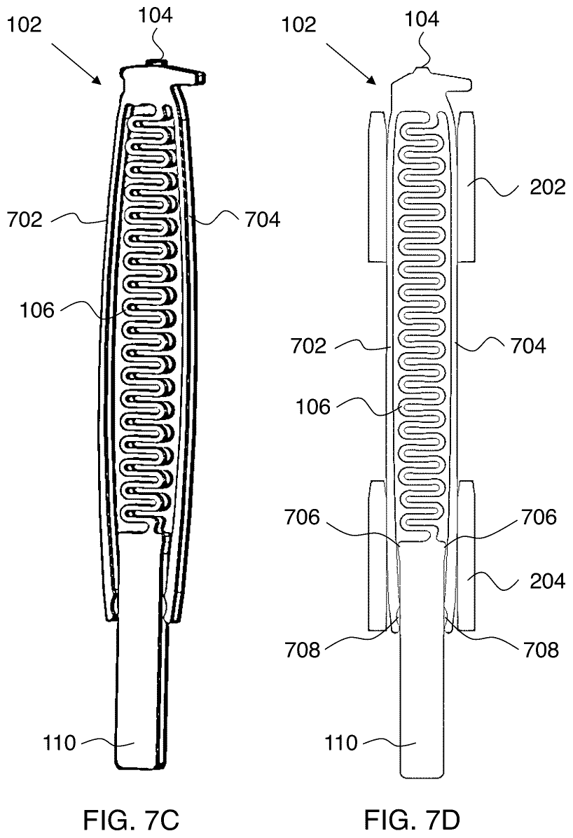

FIGS. 7A-D show a second embodiment of the invention. This is an example of the side-rail variant described above. FIGS. 7A and 7B are front and side views, respectively, of probe 102 that includes a mechanically resilient first member 106 (i.e. the “coil” as described above) and electrically conductive second members 702 and 704 (i.e., “rails” as described above). Probe 102 also includes a probe tip 110 configured to make temporary electrical contact to a device under test, and a probe base 104 configured to make electrical contact to a test apparatus. The mechanical compliance between the probe tip and the probe base is primarily determined by the mechanically resilient first member. The electrical current path between the probe tip and the probe base is primarily through the rails. The rails are affixed to the mechanically resilient first member at the probe base, as shown. FIG. 7C is an isometric view of the probe of FIGS. 7A-B. FIG. 7D shows the probe of FIGS. 7A-B disposed in guide plates 202 and 204.

In this example, probe 102 is a multilayer MEMS (micro-electrical-mechanical systems) probe having a MEMS deposition direction (left <-> right on FIG. 7B) , and the rails 702 and 704 are disposed to sandwich the mechanically resilient first member 106 in a horizontal direction perpendicular to the MEMS deposition direction, as shown on FIG. 7A. The side-rail variant is typically easier to manufacture than the rail-on-back variant. Here also, optional features can be provided to prevent excess tension from pulling the tip out of the probe. In this example, tip features 706 engage with rail feature 708 to provide tensile protection. Although it is not shown in these examples, it is also possible to control scrub motions in side-rail probes by adding suitable scrub features to the tip and/or rail.

In one exemplary design of the side-rail variant, a probe array having a grid pitch of 150 μm and a probe size of 120×50×1200 μm had the following probe performance parameters: contact force 3.3+50% grams at 75 μm overtravel, probe current carrying capacity 1.05+20% A, maximum overtravel 100 μm, bandwidth 60 GHz @ -10 dB, and 1.4 grams sidewall retention force.

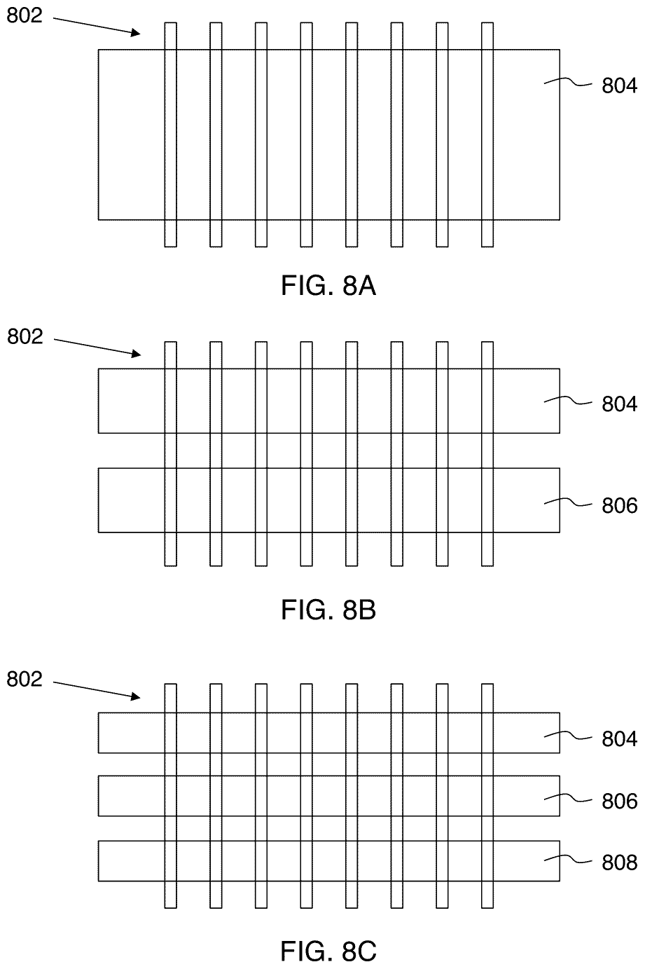

FIGS. 8A-D schematically show several probe array configurations. FIG. 8A schematically shows an example with probe array 802 disposed in a single guide plate 804. FIG. 8B schematically shows an example with probe array 802 disposed in two guide plates 804 and 806. FIG. 8C schematically shows an example with probe array 802 disposed in three guide plates 804, 806 and 808. Any number of guide plates can be employed. To better appreciate this aspect of the invention, note that conventional vertical probe arrays almost always have two well-separated and thin guide plates disposed near the base and tip ends of the probe array. The guide plate separation provides room for lateral deflection of the probes as they are vertically compressed, and the use of thin guide plates minimizes friction as probes move through the lower guide plate holes to accommodate overtravel.

Affixing the rail(s) to the coil at the probe base has the benefit of ensuring that probe overtravel is strictly a compression of the coil, and does not require any relative motion between the probe and the guide plate(s). As a result, guide plate configurations as in the examples of FIGS. 8A-C are enabled, which could not be used with arrays of conventional probes. The resulting complete or near-complete enclosure of probes by the guide plate(s) at least has the advantage of protecting the probes from mechanical damage in handling. Preferably, the vertical spacing between guide plates is small enough to prevent undesirable buckling of the probes between the guide plates. For one probe design, a guide plate spacing of 250 μm or less was found to be sufficient for this purpose, but the preferred guide plate spacing will depend on details of the probe design. Note that this design preference is completely opposite to conventional vertical probe array design, where buckling of probes between the guide plates in operation is essential.

Another variation in probe head design is use of angled guide plate holes, as schematically shown on FIG. 8D. Here probe array 812 is disposed in a single guide plate 814 having angled holes. The key parameter is the deviation angle from vertical, θ. The angle θ can be selected to define a scrub motion of the probe tips of the probe array. The following figures show several examples of these ideas.

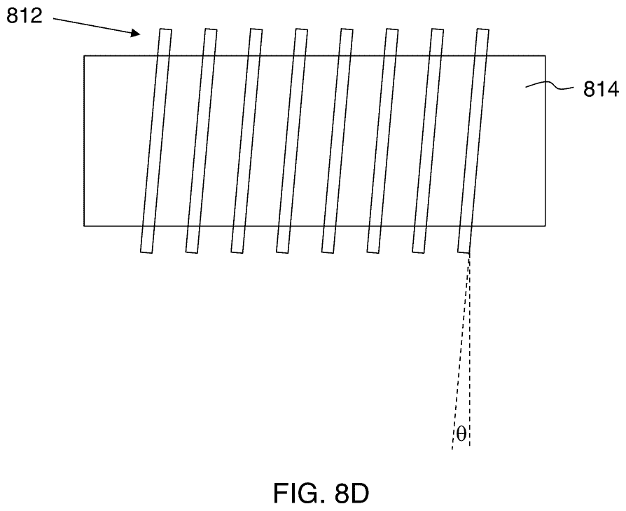

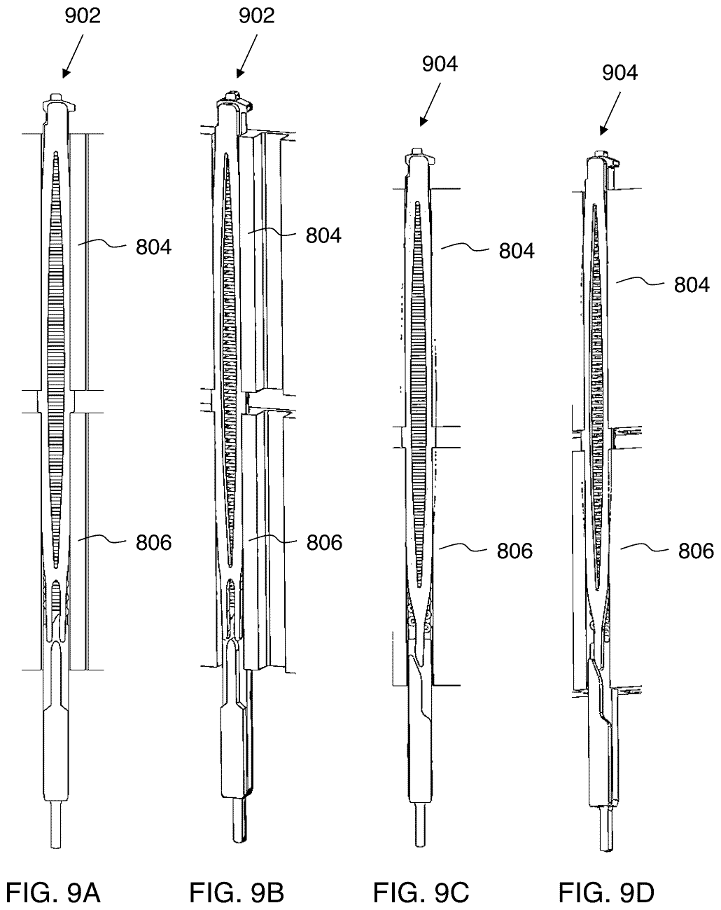

FIGS. 9A-B show an example of two guide plates. Here probe 902 is the probe of FIGS. 1A-B, and is disposed in two guide plates 804 and 806.

FIGS. 9C-D show another example of two guide plates. Here probe 904 is the probe of FIGS. 4A-B, and is disposed in two guide plates 804 and 806.

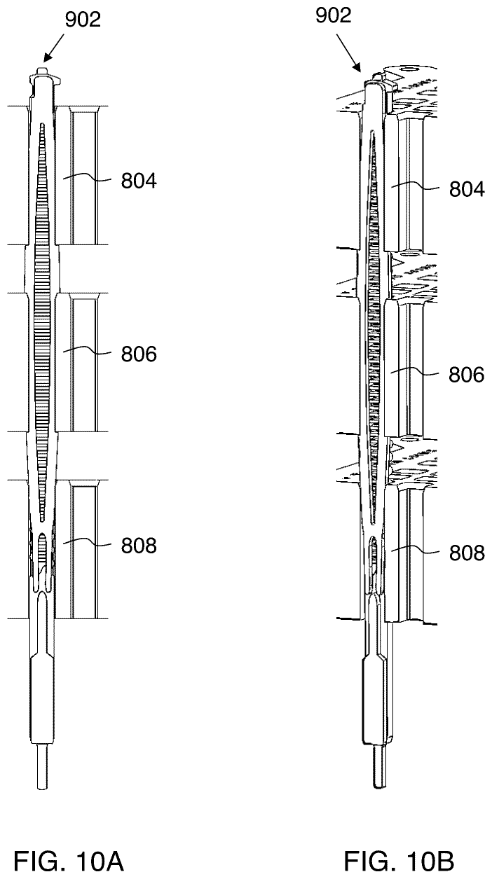

FIGS. 10A-B show an example of three guide plates. Here probe 902 is the probe of FIGS. 1A-B, and is disposed in three guide plates 804, 806 and 808.

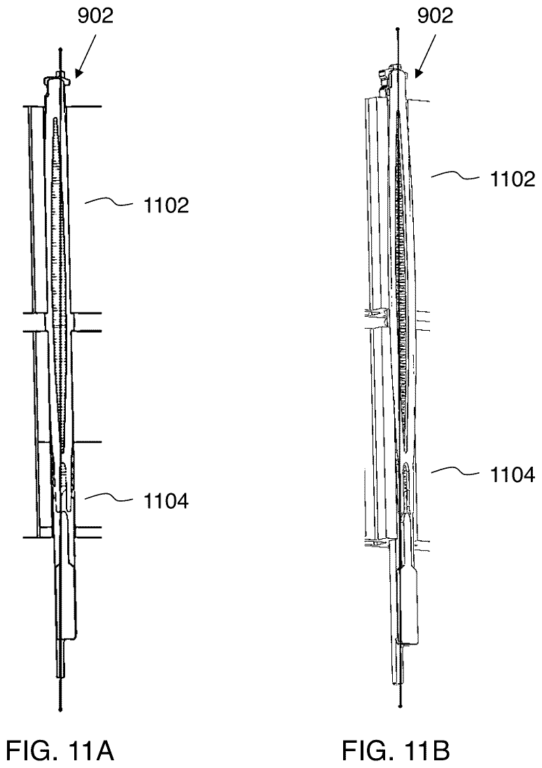

FIGS. 11A-B show a first example of guide plates with angled holes. Probe 902 is the probe of FIGS. 1A-B, and is disposed in two guide plates 1102 and 1104. Here θ is 1.2 degrees, which is small enough to enable vertical alignment of the probe base and probe tip by suitable design of the probes (e.g., a small lateral offset of the tip contact point from the base contact point).

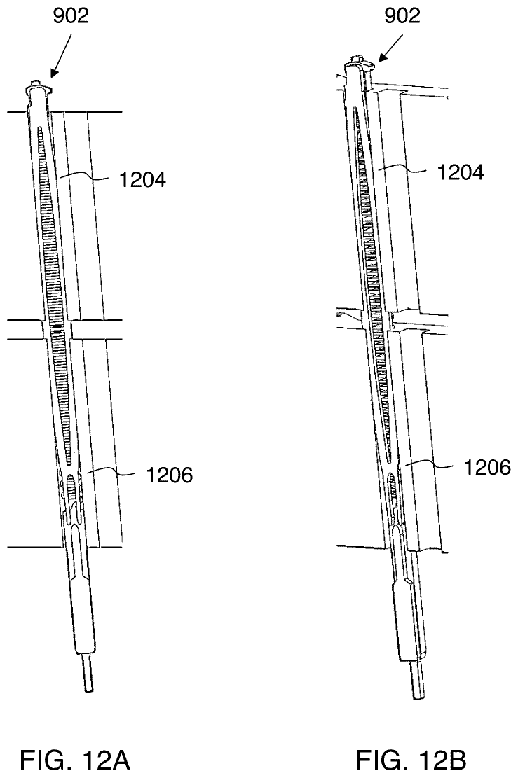

FIGS. 12A-B show a second example of guide plates with angled holes. Probe 902 is the probe of FIGS. 1A-B, and is disposed in two guide plates 1202 and 1204. Here θ is 5 degrees, which was found in one design example to be an angle suitable for providing maximum scrub motion. For larger angles like this, it is typically not possible to vertically align the probe tip and the probe base.

1. A probe for use in a vertical probe array, the probe comprising:
a mechanically resilient first member;
at least one electrically conductive second member;
a probe tip configured to make temporary electrical contact to a device under test;
a probe base configured to make electrical contact to a test apparatus;
wherein a mechanical compliance between the probe tip and the probe base is primarily determined by the mechanically resilient first member;
wherein an electrical current path between the probe tip and the probe base is primarily through the at least one electrically conductive second member;
wherein the at least one electrically conductive second member is affixed to the mechanically resilient first member at the probe base.

2. The probe of claim 1, wherein the probe is a multilayer MEMS (micro-electrical-mechanical systems) probe having a MEMS deposition direction, and wherein the at least one electrically conductive second member comprises two members disposed to sandwich the mechanically resilient first member in a horizontal direction perpendicular to the MEMS deposition direction.

3. The probe of claim 1, wherein the probe is a multilayer MEMS (micro-electrical-mechanical systems) probe having a MEMS deposition direction, and wherein the at least one electrically conductive second member comprises a member disposed above or below the mechanically resilient first member in the MEMS deposition direction.

4. The probe of claim 1, wherein the probe tip includes a tip feature that mechanically engages with a rail feature of the at least one electrically conductive second member to provide both electrical contact and a slidable mechanical contact between the probe tip and the at least one electrically conductive second member.

5. The probe of claim 4, wherein the tip feature mechanically engages with the rail feature such that protection is provided against tension undesirably pulling the probe tip out of the probe.

6. The probe of claim 5, wherein a hook on the rail feature engages with the tip feature to provide tensile protection.

7. The probe of claim 5, wherein a pincer on the rail feature engages with the tip feature to provide tensile protection.

8. The probe of claim 4, wherein a scrub motion of the probe tip during vertical compression of the probe is determined by one or more scrub features of the probe tip and/or the at least one electrically conductive second member.

9. The probe of claim 8, wherein the scrub motion includes a rotation of the probe tip about a vertical axis of the probe.

10. The probe of claim 8, wherein the scrub motion includes a lateral motion of the probe tip on a contact pad of the device under test.

11. The probe of claim 8, wherein the one or more scrub features of the probe tip and/or the at least one electrically conductive second member are selected from the group consisting of:
a slidable engagement of the at least one electrically conductive second member with an asymmetric feature of the probe tip; and
a slidable engagement of the at least one electrically conductive second member with a feature of the probe tip defining one or more back-and-forth motions.

12. A vertical probe array comprising:
two or more probes according to claim 1; and
one or more guide plates having guide plate holes in which the two or more probes according to claim 1 are disposed.

13. The vertical probe array of claim 12, wherein the guide plate holes are angled with respect to a vertical direction of the vertical probe array.

14. The vertical probe array of claim 13, wherein an angle of the guide plate holes is selected to define a scrub motion of the probe tips of the two or more probes according to claim 1.

15. A method of probing a device under test with one or more vertical probes, the method comprising:
a) providing at least one probe comprising:
a1) a mechanically resilient first member;
a2) at least one electrically conductive second member;
a3) a probe tip configured to make temporary electrical contact to a device under test;
a4) a probe base configured to make electrical contact to a test apparatus;
wherein a mechanical compliance between the probe tip and the probe base is primarily determined by the mechanically resilient first member;
wherein an electrical current path between the probe tip and the probe base is primarily through the at least one electrically conductive second member;
wherein the at least one electrically conductive second member is affixed to the mechanically resilient first member at the probe base; and
b) probing a device under test with the at least one probe.

16. The method of claim 15, wherein the at least one probe is a multilayer MEMS (micro-electrical-mechanical systems) probe having a MEMS deposition direction, and wherein the at least one electrically conductive second member comprises two members disposed to sandwich the mechanically resilient first member in a horizontal direction perpendicular to the MEMS deposition direction.

17. The method of claim 15, wherein the at least one probe is a multilayer MEMS (micro-electrical-mechanical systems) probe having a MEMS deposition direction, and wherein the at least one electrically conductive second member comprises a member disposed above or below the mechanically resilient first member in the MEMS deposition direction.

18. The method of claim 15, wherein the probe tip includes a tip feature that mechanically engages with a rail feature of the at least one electrically conductive second member to provide both electrical contact and a slidable mechanical contact between the probe tip and the at least one electrically conductive second member.

19. The method of claim 18, wherein the tip feature mechanically engages with the rail feature such that protection is provided against tension undesirably pulling the probe tip out of the at least one probe.

20. The method of claim 19, wherein a hook on the rail feature engages with the tip feature to provide tensile protection.

21. The method of claim 19, wherein a pincer on the rail feature engages with the tip feature to provide tensile protection.

22. The method of claim 18, wherein a scrub motion of the probe tip during vertical compression of the at least one probe is determined by one or more scrub features of the probe tip and/or the at least one electrically conductive second member.

23. The method of claim 22, wherein the scrub motion includes a rotation of the probe tip about a vertical axis of the probe.

24. The method of claim 22, wherein the scrub motion includes a lateral motion of the probe tip on a contact pad of the device under test.

25. The method of claim 22, wherein the one or more scrub features of the probe tip and/or the at least one electrically conductive second member are selected from the group consisting of:
a slidable engagement of the at least one electrically conductive second member with an asymmetric feature of the probe tip; and
a slidable engagement of the at least one electrically conductive second member with a feature of the probe tip defining one or more back-and-forth motions.

26. The method of claim 15, further comprising:
providing one or more guide plates having guide plate holes in which the one or more probes are disposed.

27. The method of claim 26, wherein the guide plate holes are angled with respect to a vertical direction of the vertical probe array.

28. The method of claim 27, wherein an angle of the guide plate holes is selected to define a scrub motion of the probe tips of the two or more probes according to claim 1.
